(19) United States
(12) Patent Application Publication
(10) Pub. No.: US 2013/0269755 A1
(43) Pub. Date: Oct. 17, 2013

(54) SOLAR GLASS THERMOELECTRIC INTEGRATED DEVICE

(71) Applicants: Songshun Xu, (US); Yin Xu, (US)

(72) Inventor: Songshun Xu, Nanjing (CN)

(73) Assignees: Yin Xu, Nanjing (CN); Songshun Xu, Nanjing (CN)

(21) Appl. No.: 13/782,668

(22) Filed: Mar. 1, 2013

(30) Foreign Application Priority Data
Apr. 12, 2012 (CN) 201220153449.8
Nov. 5, 2012 (CN) 201210435988.5

(51) Int. Cl. H01L 31/058

(52) U.S. Cl. CPC H01L 31/058
USPC 136/248

(57) ABSTRACT

The present invention relates to a solar glass thermoelectric integrated device, including top and bottom glass plates, a silicon photocell array assembly, a heat-exchanging plate, a heat-collecting tube, and a support bracket. The silicon photocell array assembly is laid within a hollow glass layer, a non-metal spacer bar having a molecular sieve is arranged between the top and bottom glass plates at edges, the non-metal spacer bar is sealed with the top and bottom glass plates by using a silicone sealant, the glass plates are wrapped at an outer side by a frame having a hanging edge, the hanging edge of the frame is hooked to a rectangular frame formed by a support keel, and the rectangular frame is fixed to an installation surface by using the support bracket. The present invention is capable of using thermal energy, obtaining electrical energy, reducing temperature of the photocell, and ensuring proper power generation thereof.

### CROSS-REFERENCE TO RELATED APPLICATIONS

This application claims priority to Chinese Patent Application No. 201220153449.8, filed Apr. 12, 2012 and Chinese Patent Application No. 201210435988.5, filed Nov. 5, 2012, all of which are hereby incorporated by reference in their entirety.

### FIELD OF THE INVENTION

The present invention relates to a solar glass thermoelectric integrated device, and pertains to the field of solar thermoelectric integration technologies.

### BACKGROUND OF THE INVENTION

Composite layers of a common flat-plate solar photovoltaic assembly are made up of glass, EVA, a silicon cell, EVA, a backsheet (tedlar-polyester-tedlar, TPT), a frame, and the like arranged from top to bottom. EVA stands for Ethylene Vinyl Acetate, a popular thermosetting tacky film used to bound articles and particularly useful for bounding electronic parts assembly and optical products for its bounding property, durability and optical characteristics. The glass is normally ultra white high-transmission tempered glass which may protect the silicon cell. The EVA glue is used to bind the glass and the silicon cell and squeeze out air between the glass and the silicon cell, thereby providing a sealing function. The backsheet (TPT) on the back also has functions of sealing and protecting the silicon cell. The power generation principle thereof is as follows: Sunlight goes through the surface glass and the EVA and is incident upon the surface of the silicon cell; after being absorbed by the silicon cell, a small part of the sunlight is converted into electrical energy for power generation, and a large part of the sunlight is changed into thermal energy and radiated into the air, where utilization efficiency of the solar energy is low.

A common flat-plate solar water heater is made up of glass, a heat collector (where a copper pipe or an aluminum pipe is provided on the sheet core), a heat insulation layer, a sealing ring, a backsheet, a frame, and the like. The working principle is as follows: Sunlight goes through the surface glass and is incident upon the heat collector to heat up the sheet core and water in the copper pipe or aluminum pipe; then, hot water flows into a heat-preservation water tank, where cold water flows in and hot water flows out at the same time. This operation cycle is repeated. The thermal utilization efficiency of the solar energy is also low in this method.

### SUMMARY OF THE INVENTION

The technical problem to be solved by the present invention is to overcome the disadvantage of the prior art and to provide a solar glass thermoelectric integrated device. The device is capable of generating power, using remaining heat generated from photoelectric conversion, and converting light energy absorbed by a gap for laying a silicon photocell and peripheral blank spaces into thermal energy.

In order to solve the above technical problem, the present invention provides a solar glass thermoelectric integrated device including a support bracket having a rectangular installation frame, where a hollow solar assembly, a heat-exchanging plate, a heat-collecting tube, and an insulation layer are arranged in the rectangular installation frame of the support bracket from top to bottom. The hollow solar assembly includes top and bottom glass plates, a silicon photocell array assembly, a spacer bar, and a frame. The silicon photocell array assembly is compounded on an upper surface of the bottom glass plate. The spacer bar is arranged between the top and bottom glass plates at edges, and is sealed with and connected to the top and bottom glass plates by using a sealant. The frame is mounted to the edges of the sealed top and bottom glass plates. The insulation layer is provided with grooves arranged along a vertical direction of the support bracket on an upper surface. The heat-collecting tube is embedded in the grooves, and the heat-collecting tube is connected to a main heat-collecting tube arranged along a horizontal direction of the support bracket at two ends which extend beyond the support bracket. The heat-exchanging plate is provided with a notch below for clamping with the heat-collecting tube, and an upper surface of the heat exchanger is a flat surface which fits into a lower surface of the bottom glass plate of the hollow solar assembly.

The present invention further defines the following technical solution for the above solar glass thermoelectric integrated device: The support bracket includes a support keel and a base, and the support keel includes a vertical keel and a horizontal keel. The vertical keel and the horizontal keel are both of a U-shaped groove structure. The vertical keel has symmetrical convex portions at two sides, and the vertical keel is provided with opening slots spaced apart from each other in a shape which is the same as a cross section of the horizontal keel. A length of the horizontal keel is equal to a distance between two adjacent vertical keels, and the horizontal keel is provided with flanges at two ends and is clamped with the opening slots on the vertical keel by using the flanges at the two ends of the horizontal keel, thereby forming the rectangular installation frame for mounting the solar cell assembly. The base is provided with an opening slot in a shape which is the same as a cross section of the vertical keel, concave portions matching the convex portions are provided within the opening slot of the base, and the vertical keel is inserted into the base along the concave portions of the opening slots. The frame has hooking structures on four edges, thereby hooking the hollow solar assembly to the rectangular installation frame of the support keel by using the hooking structures.

For the above solar glass thermoelectric integrated device, a rubber pad is further provided between an outer side of the top and bottom glass plates and the frame, thereby reducing heat conduction between the glass and the frame and protecting the glass to reduce an external impact.

For the solar glass thermoelectric integrated device, a highly efficient graphite heat-conducting layer is further provided between the bottom glass plate and the heat-exchanging plate. The heat-conducting layer is used to absorb thermal energy efficiently and conduct heat to the heat-exchanging plate efficiently, thereby heating up the heat exchanger by using the heat-exchanging plate.

For the solar glass thermoelectric integrated device, an opening distance of the U-shaped groove of the horizontal keel is smaller than an opening distance of the U-shaped groove of the vertical keel in the support bracket. The U-shaped groove of the vertical keel has a function of guiding a flow, and is capable of quickly guiding rainwater. In addition, a cover plate having a T-shaped cross section is provided at the opening of the U-shaped groove of the vertical keel, thereby preventing external articles from entering the U-shaped groove which may otherwise affect rainwater flow guiding.

For the solar glass thermoelectric integrated device, the hollow solar assembly is filled with inert gas, thereby squeezing out air in the hollow glass by using the inert gas, reducing an oxidation rate of cells, and prolonging the service life of the device.

For the solar glass thermoelectric integrated device, the grooves of the insulation layer are arranged in parallel with equal distances, and the heat-collecting tube is a structure made up by welding parallel and equidistant copper tubes, and matches the grooves of the insulation layer. The copper tubes are laid as a whole to run through the support bracket, thereby laying the copper tubes as a whole during installation, reducing installation steps, improving stability of the device, reducing the number of pipe joints, and reducing the failure rate of the heat exchanger.

For the solar glass thermoelectric integrated device, a maintenance ladder is provided along the vertical direction of the support bracket and vertically parallel to an upper surface of the hollow solar assembly, and a rail is provided horizontally along top and bottom ends of the support bracket, where the maintenance ladder is movably mounted to the rail by using a pulley assembly. The maintenance ladder is adaptable and may be adjusted according to an incident angle of sunlight, thereby ensuring that incidence of sunlight is not affected by the maintenance ladder.

For the solar glass thermoelectric integrated device, a cleaning apparatus fitting into the upper surface of the hollow solar assembly is provided at a lower part of the maintenance ladder, so that the surface of the hollow glass layer is cleaned in a process of horizontally moving the maintenance ladder, thereby improving photoelectric conversion efficiency.

Further, for the solar glass thermoelectric integrated device, the non-metal spacer bar is a rectangular hollow tube structure, and two raised bars are provided on contact surfaces between the rectangular hollow tube and the top and bottom glass plates, thereby retaining a sealant between the two raised bars, avoiding poor sealing caused by an uneven sealant on the spacer bar which may affect the sealing effect and shorten the service life of the silicon photocell. The non-metal spacer bar is provided with a white fluoride coating on a side facing the silicon photocell array assembly, thereby reducing thermal loss caused by heat conduction, protecting the non-metal spacer bar from aging when exposed to the sun for a long period, and prolonging the service life of the non-metal spacer bar.

The beneficial effects of the present invention are that, the present invention is capable of generating power, using the remaining heat generated from photoelectric conversion, and converting light energy absorbed by a gap for laying a silicon photocell and peripheral blank spaces into thermal energy. The key technology of the apparatus lies in transferring the thermal energy to the heat exchanger, thereby collecting, storing, and using the light heat and the remaining heat to the utmost, using the thermal energy, obtaining the electrical energy, reducing the temperature of the photocell, and ensuring proper power generation. Under the current circumstances of a limited building space, space utilization may be greatly improved, more devices may be installed within a limited space, and electrical and thermal energy may be obtained at the same time.

### BRIEF DESCRIPTION OF THE DRAWINGS

FIG. 1 is a schematic structural diagram according to one aspect of the present invention;

FIG. 2 is a schematic diagram of a structure connected by a keel according to one aspect of the present invention; and

FIG. 3 is a schematic diagram of a structure connected by a keel according to one aspect of the present invention.

### DETAILED DESCRIPTION OF THE EMBODIMENTS

### Embodiment 1

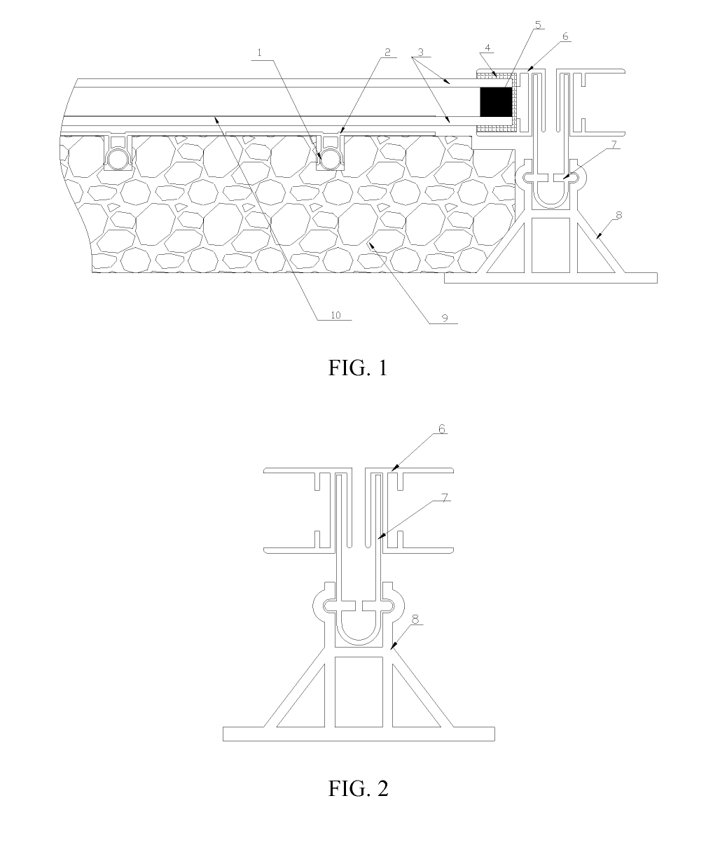

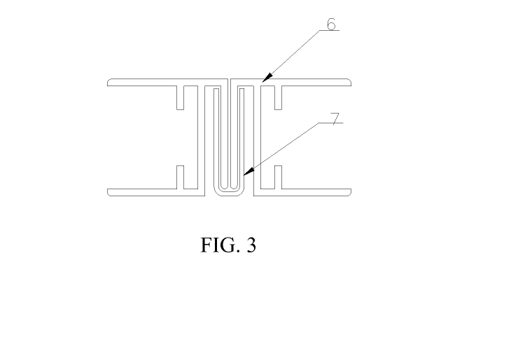

FIG. 1 to FIG. 3 show a structure of a solar glass thermoelectric integrated device provided by the embodiment. The solar glass thermoelectric integrated device includes glass plates 3, a silicon photocell array assembly 10, a heat-exchanging plate 2, a heat-collecting tube 1, a support keel 7, and a support bracket 8. The silicon photocell array assembly 10 is laid within top and bottom glass plates. A non-metal spacer bar 5 having a molecular sieve is arranged within the top and bottom glass plates at edges, and the non-metal spacer bar 5 is sealed with the top and bottom glass plates by using a silicone sealant. A hollow solar assembly is filled with inert gas. The non-metal spacer bar is provided with a white fluoride coating on a side facing the silicon photocell array assembly, thereby reducing thermal loss caused by heat conduction, protecting the non-metal spacer bar from aging when exposed to the sun for a long period, and prolonging the service life of the non-metal spacer bar. The top and bottom glass plates are wrapped at an outer side by a frame 6 having a hanging edge. A rubber pad 4 is further provided between the frame and the glass plates 3. The hanging edge of the frame 6 is hooked to the support bracket formed by the support keel 7. An opening distance of a U-shaped groove of a horizontal keel in the rectangular frame formed by the support keel 7 is smaller than an opening distance of a U-shaped groove of a vertical keel. The frame is fixed to an installation surface by using the support bracket. An insulation layer 9 is filled below the hollow solar assembly, and the insulation layer 9 is provided with equidistant and parallel grooves on an upper surface. The heat-collecting tube 1 is arranged within the grooves. A notch is provided below the heat-exchanging plate 2 for clamping with the heat-collecting tube 1, and an upper surface of the heat-exchanging plate 2 fits into a highly efficient graphite heat-conducting layer of a lower surface of the bottom glass plate.

In the embodiment, the heat-collecting tube is made up by welding equidistant and parallel copper tubes, and the copper tubes are laid as a whole to run through a vertical length of the support bracket, thereby laying the copper tubes as a whole during installation, reducing installation steps, improving stability of the device, and reducing the failure rate of a heat exchanger. In addition, a maintenance ladder is provided along a vertical direction of the frame on an upper surface of the hollow solar assembly, a rail is provided horizontally at top and bottom ends of the support bracket, the maintenance ladder is movably mounted to the rail by using a pulley assembly, and a cleaning apparatus fitting into an upper surface of the top glass plate is provided at a lower part of the maintenance ladder for cleaning the surface of the hollow glass.

In the embodiment, the top glass of the glass plate 3 is 3.2 mm ultra white tempered glass whose light transmission rate is up to 90%. The upper surface of the bottom glass of the glass plate 3 is compounded with the silicon photocell array assembly 10 by using an EVA film. The two-layer glass is laminated with the non-metal spacer bar 5 and a silicone sealant at edges to form the hollow solar assembly. The hollow layer is filled with inert gas. The spacer bar is filled with a molecular sieve for absorbing residual moisture and air in the hollow layer, thereby protecting the silicon cell from oxidizing. No further protection is required for the surface of the silicon cell, which reduces light transmission loss by one layer and improves power generation efficiency of the silicon cell. The silicon cells may be arranged in different modes such as 6×12, 6×6, and 8×9 in series or in parallel. The arrangement mode may be designed according to actual power generation application requirements for selecting proper installed capacity. A lead of the silicon cells connected in series or in parallel is connected to a junction box, and may be routed out at a side of the insulation layer 9. The rubber pad 4 is clamped on the edges of the hollow glass solar assembly for heat insulation, and then the frame 6 is clamped on the rubber pad to package the hollow solar assembly.

The heat-exchanging plate 2 is arranged below the hollow solar assembly, the heat-exchanging plate 2 has a slot below, and the heat-collecting tube 1 is clamped with the slot of the heat-exchanging plate. An insulation material 9 is provided below the entire device, and finally, all hollow solar assemblies are clamped and fixed to a rectangular frame formed by connection grooves of the support keel, and a stainless support is provided below the frame, so that all hollow glass solar assemblies may be retained on the same plane, which provides an elegant appearance matching a building roof

Considering the change of incident angles of sunlight in four seasons of a year, the thickness of the top glass, and the thickness of the hollow layer, a specific distance is reserved between a position on the bottom glass plate for placing the silicon photocell array assembly 10 and the frame, thereby ensuring that sunlight within a range of 140° is collected and improving the power generation efficiency of the silicon cell. A selective heat absorption coating is provided on edges of the bottom glass plate where no silicon photocell array assembly 10 is provided, thereby improving a heat absorption rate of the heat-exchanging plate.

The present invention may also have other embodiments in addition to the foregoing embodiments. Variations including technical solutions derived by equivalent replacement or change shall fall within the protection scope of the claims of the present invention.

What is claimed is:

1. A solar glass thermoelectric integrated device, comprising:
at least one solar assembly including an installation frame having mounting grooves, a silicon photocell array assembly disposed in the installation frame, a heat-exchanging plate and a heat-collecting tubing attached to the silicon photocell array assembly, an insulation layer disposed on a backside on the heat-exchanging plate, and an electric junction box; and
a supporting structure including support brackets having members configured for engaging the mounting grooves and supporting the at least one solar assembly in a pre-determined position relative to incident light, wherein:
the installation frame is a rectangular structure provided with (i) first and second sidewalls configured for sandwiching the silicon photocell array assembly, (ii) third and fourth sidewalls disposed orthogonally to the first and second sidewalls and spaced apart to form the mounting grooves, and (iii) locking fixtures detachably coupling portions of the installation frame in a pre-determined order;
the silicon photocell array assembly includes a top glass plate, a bottom glass plate, a silicon photocell array assembly disposed on an inner surface of the bottom glass plate, and a spacer disposed between the top and bottom glass plates along periphery thereof; and
the heat-collecting tubing is disposed in slots of the heat-exchanging plate and coupled to an extension tube mounted on the supporting structure.

2. The device of claim 1, wherein each of said support brackets comprises a base and a keel moveably connected to the base, wherein:
the base is provided with concave groves disposed longitudinally within interior sidewalls of the base, said interior sidewalls are spaced apart for housing portions of sidewalls of the keel; and
the keel is a U-shaped structure having two sidewalls that are (i) spaced apart for selective engaging the mounting grooves of installation frames located adjacent to one another, and (ii) provided with convex extensions matching the concave groves and movably connecting the keel to the base.

3. The device of claim 2, wherein the base further comprises flanges configured for connecting the bases to one another to form the supporting structure of a pre-determined configuration.

4. The device of claim 1, further comprising a rubber pad disposed between (i) inner surfaces of the first and second sidewalls of the installation frame and (ii) outer surfaces of the top and bottom glass plates.

5. The device of claim 1, further comprising a graphite heat-conducting layer disposed between the bottom glass plate and the heat-exchanging plate.

6. The device of claim 1, wherein the silicon photocell array assembly is a fluid-tight assembly filled with inert gas.

7. The device of claim 1, wherein the heat-collecting tubing is a copper-tubing conduit which sections are disposed substantially equidistantly from each other.

8. The device of claim 1, further comprising a service rail, a pulley assembly, and a maintenance ladder movably connected to the service rail by the pulley assembly.

9. The device of claim 8, further comprising a cleaning apparatus adapted for cleaning exterior surfaces of the at least one solar assembly.

10. The device of claim 1, wherein the spacer comprises a coating forming fluid-tight seals between (i) the spacer and the top glass plate and (ii) the spacer and the bottom top glass plate.

11. The device of claim 1, wherein the spacer is a non-metal rectangular hollow tube structure.

12. The device of claim 11, wherein surfaces of the spacer exposed to the top and bottom glass plates are provided with raised contact sections.

13. The device of claim 11, wherein an exposed to the silicon photocell array assembly portion of a sidewall of the spacer is provided with a protective white fluoride coating.

14. The device of claim 1, wherein the heat-collecting tubing is clamped to the heat-exchanging plate.

15. The device of claim 1, wherein the heat-collecting tubing is adapted for conducting a heat-transferring fluid.
